(19) United States
(12) Patent Application Publication
(10) Pub. No.: US 2026/0343770 A1
(43) Pub. Date: Oct. 29, 2026

(54) Protector

(71) Applicant: HYUNDAI MOBIS CO., LTD., Seoul (KR)

(72) Inventor: Kyeong Jun LEE, Yongin-si (KR)

(73) Assignee: HYUNDAI MOBIS CO., LTD., Seoul (KR)

(21) Appl. No.: 19/384,189

(22) Filed: Nov. 10, 2025

(30) Foreign Application Priority Data
Feb. 27, 2025 (KR) 10-2025-0025545

(51) Int. Cl. H05K 5/06

(52) U.S. Cl. CPC H05K 5/061

(57) ABSTRACT

A protector configured to fit with a housing, includes: a first body including a first receiving space therein; a first neck coupled to an upper end of the first body; a first head coupled to an upper end of the first neck; and a first ring arranged in the first receiving space and in contact with an inner surface of the first body, wherein the housing includes a fastening hole formed on at least a portion of one surface thereof, and when the first body fits with the fastening hole, the first head is formed to be positioned outside the housing, and the first neck is formed to be positioned inside the fastening hole. The protector provides an effect of closing the fastening hole to prevent foreign material from passing through the fastening hole and scattering toward the inside of the control apparatus for vehicle.

### CROSS-REFERENCE TO RELATED APPLICATION

The present application claims priority to Korean Patent Application No. 10-2025-0025545, filed on Feb. 27, 2025, the entire contents of which is incorporated herein for all purposes by this reference.

### TECHNICAL FIELD

The disclosure relates to a protector. More specifically, the disclosure relates to a protector for preventing the ingress of foreign material.

### BACKGROUND ART

The content described in this section merely provides background information for the disclosure and does not constitute the related art.

The vehicle is equipped with a control apparatus for vehicle such as an ECU (electronic control unit), or MCU (microcontroller unit) that controls various devices. The control apparatus for vehicle receives information from sensors, switches, or the like installed in respective parts of the vehicle, and processes the received information or performs control operations. The control apparatus for vehicle performs various control operations to improve the riding comfort and driving safety of the vehicle and to provide various conveniences to the driver and passengers.

The control apparatus for vehicle includes a housing and a PCB (printed circuit board) accommodated inside the housing, and the PCB includes electronic components. The housing includes a fastening hole formed on one surface thereof and the PCB includes a fastening hole formed on at least a portion thereof, and a bolt and a nut are coupled to each fastening hole. The housing and the PCB may be fastened by screw coupling.

The housing may be formed by coupling a plurality of plates. When the housing is formed by coupling the plurality of plates, each plate may be coupled using a bolt and a nut. Each plate includes a fastening hole, and the bolt and the nut are inserted into each fastening hole.

When the PCB and the plate are coupled by screw coupling, the durability of the control apparatus for vehicle may be improved, and the PCB and the plates may be firmly coupled. However, when the PCB and the plates are screw-coupled, a gap may be formed between the threads of the bolt or the nut.

When impact or vibration is continuously applied to the control apparatus for vehicle, the gap between the threads may widen, and the bolt and the nut may become loosened. To prevent the bolt or the nut from loosening, thread fixing paint or screw locking paint may be applied. When the screw locking paint is applied, the screw locking paint is applied to the gap formed between the threads.

FIG. 1 is a perspective view illustrating an embodiment of a conventional screw coupling.

Referring to FIG. 1, a housing 11 includes a fastening hole 13 formed on at least a portion of one surface thereof. When the bolt 20 is not fastened to the fastening hole 13, the fastening holes 13 may serve as passages through which foreign material may flow toward the inside of the housing 11. When the foreign material passes through the fastening hole 13 and reaches the inside of the housing 11, the foreign material B may freely fall and come into contact with the PCB 15. When the foreign material comes into contact with the PCB 15, the performance of a control apparatus for vehicle 10 may deteriorate, or a circuit formed on the PCB 15 may cause a short circuit.

When the housing 11 and a mounting bracket 12 need to be coupled, they may be screw-coupled using the bolt 20. The housing 11 may include the fastening hole 13 on at least a portion thereof, and the mounting bracket 12 may include an auxiliary fastening hole 14 on at least a portion thereof. The fastening hole 13 and the auxiliary fastening hole 14 may be formed using a tapping process. The tapping process is a process of forming threads on an inner surface of the hole. A hole is formed on one surface of the housing 11 and the mounting bracket 12, and the threads is formed using a tap. The tab is a cutting tool that forms threads on the inner surface of the hole.

When the housing 11 and the mounting bracket 12 need to be coupled, one surface of the housing 11 and one surface of the mounting bracket 12 are brought into contact with each other. The fastening hole 13 and the auxiliary fastening hole 14 are arranged to overlap each other. When a process of coupling the bolt 20 to the fastening hole 13 or the auxiliary fastening hole 14 is performed, powder A may be generated from the housing 11 or the bolt 20. When the housing 11, the mounting bracket 12, or the bolt 20 includes a metallic material, a metallic powder may be generated due to wear. The metallic powder A may scatter toward the inside of the housing 11. The scattered powder A may freely fall and come into contact with the PCB 15. When the metallic powder comes into contact with the PCB 15, the performance of the control apparatus for vehicle 10 may deteriorate, or a circuit formed on the PCB 15 may cause a short circuit.

Even after the control apparatus for vehicle 10 is completed by performing the process of coupling the bolt 20 to the fastening hole 13, the metallic powder may be generated. When impact or vibration is continuously applied to the control apparatus for vehicle 10, frictional force be generated in the threads of the bolt 20 or the nut. Due to the frictional force, the housing 11, the mounting bracket 12, the bolt 20, or the nut may wear out, and metallic powder A may be generated. The metallic powder may scatter toward the inside of the housing 11 and may come into contact with the PCB 15.

### DISCLOSURE OF INVENTION

### Technical Problem

An aspect of the disclosure is to provide a protector that may fit with a fastening hole when the control apparatus for vehicle includes the fastening hole on at least a portion thereof.

According to an embodiment of the disclosure, an aspect of the disclosure is to provide a protector formed to surround an end portion of a bolt when the bolt is screw-coupled to one surface of the housing and the end portion of the bolt is exposed toward the inside of the housing.

According to an embodiment of the disclosure, an aspect of the disclosure is to provide a protector that further includes a ring therein and allows the ring to fit with threads of the bolt so that the bolt may be attached to the housing without applying screw locking paint.

According to an embodiment of the disclosure, an aspect of the disclosure is to provide a protector that further includes a ring therein and allows the ring to fit with threads of the bolt so that vibration or impact may be absorbed.

### Solution to Problem

According to an embodiment of the disclosure, there is provided a protector configured to fit with a housing, including: a first body including a first receiving space therein; a first neck coupled to an upper end of the first body; a first head coupled to an upper end of the first neck; and a first ring arranged in the first receiving space and in contact with an inner surface of the first body, wherein the housing includes a fastening hole formed on at least a portion of one surface thereof, and when the first body fits with the fastening hole, the first head is formed to be positioned outside the housing, and the first neck is formed to be positioned inside the fastening hole.

According to an embodiment of the disclosure, there is provided a protector configured to fit with a housing, including: a second body including a second receiving space therein; a second neck coupled to an upper end of the second body; a second head coupled to an upper end of the second neck; and a second ring formed in the second receiving space and in contact with an inner surface of the second body, wherein the housing includes a fastening hole formed on at least a portion of one surface thereof, and a mounting bracket is formed outside the housing, the mounting bracket includes an auxiliary fastening hole formed on at least a portion of one surface thereof, and when the fastening hole and the auxiliary fastening hole are screw-coupled using a bolt, the second receiving space is formed such that the bolt is positioned therein, and when the second body fits with the fastening hole, the second head is formed to be positioned outside the housing, and the second neck is formed to be positioned inside the fastening hole.

### EFFECTS OF DISCROSURE

According to an embodiment of the disclosure, the protector provides an effect of closing the fastening hole to prevent foreign material from scattering toward the inside of the control apparatus for vehicle through the fastening hole.

According to an embodiment of the disclosure, the protector provides an effect of closing the fastening hole by surrounding an end portion of the bolt to prevent powder generated by wear of the threads of the bolt from scattering.

According to an embodiment of the disclosure, the protector provides an effect of allowing a ring to fit with threads of the bolt so that the bolt may be attached to the housing without applying screw locking paint.

According to an embodiment of the disclosure, the protector provides an effect of allowing a ring to fit with threads of the bolt to absorb vibration or impact.

### BRIEF DESCRIPTION OF THE DRAWINGS

FIG. 1 is a perspective view illustrating an embodiment of a conventional screw coupling.

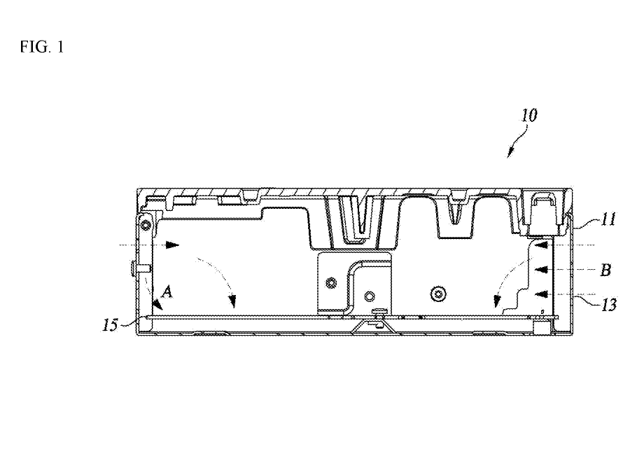

FIG. 2 is an exploded perspective view of a protector according to an embodiment of the disclosure.

FIG. 3 is a diagram illustrating a usage state of a first protector and a second protector according to an embodiment of the disclosure.

### DETAILED DESCRIPTION FOR CARRYING OUT THE INVENTION

Hereinafter, some embodiments of the disclosure will be described in detail with reference to illustrative drawings. It should be noted that, in adding reference numerals to the components in each drawing, the same reference numerals are used for the same components as much as possible, even if they are shown in different drawings. In addition, in describing the disclosure, when it is determined that a specific description of a related known configuration or function may obscure the gist of the disclosure, a detailed description thereof will be omitted.

In describing the components of the embodiments according to the disclosure, reference numerals such as first, second, i), ii), a), and b) may be used. These numerals are merely used to distinguish one component from another component, and do not limit the nature, order, sequence, or the like of that components by such numerals. In the specification, when a part is described as “comprising” or “including” a certain component, it means that other components may be further included instead of excluding other components unless explicitly stated to the contrary.

In describing the components of the disclosure, the terms such as first, second, A, B, (a), (b) may be used. These terms are merely used to distinguish one component from another component, and do not limit the nature, order, sequence, or the like of that components by the terms.

When a component is described as being “connected,” “coupled,” or “joined” to another component, it should be understood that the component may be directly connected or joined to the other component, but that another component may be “connected,” “coupled,” or “joined” between the components.

Unless described otherwise, it should be noted that the description of any one embodiment may be applied to other embodiments.

The description of the invention disclosed below in conjunction with the accompanying drawings is intended to describe exemplary embodiments of the disclosure and is not intended to represent the only embodiment in which the disclosure may be practiced.

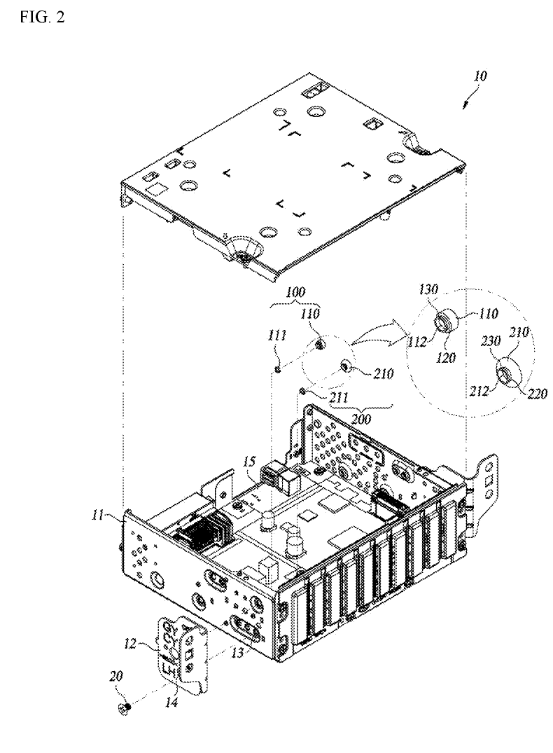

FIG. 2 is an exploded perspective view of a protector according to an embodiment of the disclosure.

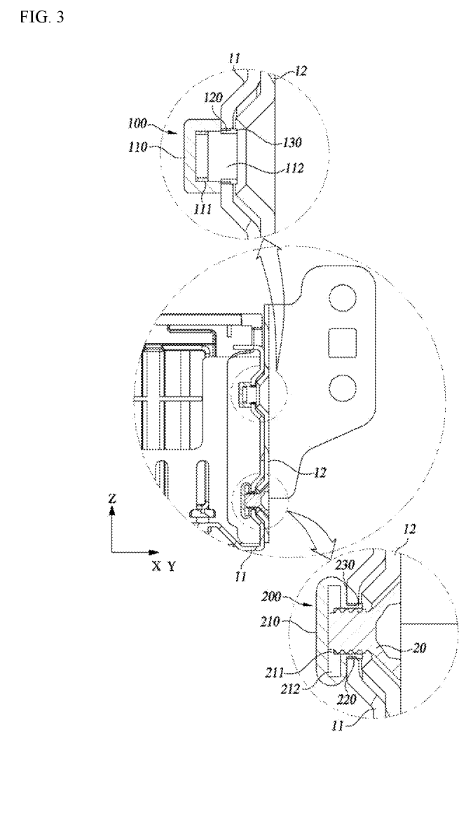

FIG. 3 is a diagram illustrating a usage state of a first protector and a second protector according to an embodiment of the disclosure.

Referring to FIGS. 2 and 3, a first protector 100 according to an embodiment of the disclosure includes a first body 110 including a first receiving space 112 therein, a first neck 120 coupled to an upper end of the first body 110, and a first head 130 coupled to an upper ends of the first neck 120. A first ring 111 is arranged inside the first receiving space 112, and is coupled to an inner surface of the first body 110.

A control apparatus for vehicle 10 according to an embodiment of the disclosure includes a housing 11 that accommodates a PCB 15 therein, and a fastening hole 13 formed on at least a portion of one surface of the housing 11. The first protector 100 fits with the fastening hole 13. The fitting is a coupling method commonly used in mechanical inventions or structures. The fitting refers to a coupling method in which components engage with each other. Since the fitting utilizes interference between the components to couple them, it has an advantage in that the components may be fixed by themselves without additional components such as adhesives or bolts.

When the component to be coupled are fitted to each other, the structure may be maintained over time, thereby providing an advantage of extending the lifespan. Since fitting is a coupling using a frictional force between the components, it has advantages in that durability is improved and it is resistant to mechanical wear and impact.

The fitting is mainly divided into a clearance fit, a precision fit and an interference fit, depending on the size of the spacing between the components to be coupled.

The clearance fit is a type of fit in which coupled components are free to move with some spacing, and it is also called a flexible fit. For example, a shaft and a bearing are fitted using a clearance fitting method, and the shaft is surrounded by the bearing and smoothly performs rotational motion. The clearance fit is used when coupled components are engaged with each other but need to perform rotational motion or linear motion in different directions.

The precision fit is a type of fit in which coupled components have a very fine spacing, and the components are precisely coupled while allowing only a small amount of play. For example, the precision fit is used for fitting gear components of a mechanical watch or for coupling between turbine blades and a shaft of an aircraft engine.

The interference fit is a type of fit in which components are forcibly inserted and coupled very tightly, and it is also called a press fit. When components are fitted using the interference fit, dimensional interference between the components increases, enabling very strong coupling without the need for adhesives. After the components are interference-fitted, the frictional force between the components increases, making the coupling difficult to loosen. When components that should not move are fitted using an interference fit, there is an advantage in that the components may be fixed so that they cannot move. Therefore, the interference fit is suitable when a component to be fitted needs to be fixed.

According to an embodiment of the disclosure, the first protector 100 is interference-fitted with the fastening hole 13 to close the housing 11. When the first protector 100 is fitted to the fastening hole 13, the first body 110 is positioned inside the housing 11. The first head 130 is positioned outside the housing 11, and the first neck 120 is positioned inside the fastening hole 13.

At least a portion of the first head 130 is in contact with the outer surface of the housing 11, and at least a portion of the first body 110 is in contact with an inner surface of the housing 11. When the first head 130 and the outer surface of the housing 11 are in contact with each other, a frictional force may be generated, allowing the first head 130 to be fixed.

The first head 130 is formed to have an annular shape, so that the first receiving space 112 of the first body 110 is exposed. The outer diameter of the first head 130 is formed to be greater than a diameter of the fastening hole 13. When the first protector 100 is fitted to the fastening hole 13, at least a portion of the first head 130 is exposed toward the outside of the control apparatus for vehicle 10. The first head 130 may secure the first protector 100. When a force directed toward the inside of the control apparatus for vehicle 10 is applied to the first protector 100, the first protector 100 does not detach from the fastening hole 13.

The first body 110 may include the first receiving space 112 therein. The first receiving space 112 is exposed toward the outside of the control apparatus for vehicle 10. The foreign material introduced from the outside of the control apparatus for vehicle 10 scatters toward the fastening hole 13, but does not fall toward the inside of the housing 11, and accumulates in the first receiving space 112.

The first body 110 is formed to have a diameter greater than the diameter of the fastening hole 13. When the first protector 100 is fitted to the fastening hole 13, the first body 110 is positioned toward the inside of the housing 11, and at least a portion of the first body 110 comes into contact with the inner surface of the housing 11. A frictional force is generated between the first body 110 and the inner surface of the housing 11, allowing the first body 110 to be fixed. When a force directed toward the outside of the control apparatus for vehicle 10 is applied to the first protector 100, the first protector 100 does not detach from the fastening hole 13.

The first ring 111 may be positioned inside the first receiving space 112. The first ring 111 contacts an inner surface of the first receiving space 112 while being formed to be movable. The outer diameter of the first ring 111 is formed to be greater than the diameter of the fastening hole 13 so that the first ring 111 does not detach toward the outside of the first receiving space 112.

The first neck 120 couples the first body 110 and the first head 130. The first neck 120 is formed to have an annular shape, so that the first receiving space 112 of the first body 110 is exposed. The first neck 120 is formed such that the first body 110 and the first head 130 are spaced apart from each other by a predetermined distance, where the predetermined distance is formed to be equal to or less than a thickness of the housing 11. When the first protector 100 is fitted to the fastening hole 13, the first neck 120 is in close contact with the fastening hole 13.

According to an embodiment of the disclosure, after performing the process of fitting the first protector 100 to the fastening hole 13, a screw (not shown) or a component (not shown) including the screw may be coupled to the fastening hole 13. The screw is positioned in the first receiving space 112. The first ring 111 and the screw are attached to each other, and the screw moves the first ring 111 by the attachment force. When performing a process of fastening the screw, one end of the screw pushes the first protector 100, so that the shape of the first protector 100 may be deformed.

FIG. 2 is an exploded perspective view of a protector according to an embodiment of the disclosure.

FIG. 3 is a diagram illustrating a usage state of a first protector and a second protector according to an embodiment of the disclosure.

Referring to FIGS. 2 and 3, a second protector 200 according to an embodiment of the disclosure includes a second body 210 including an auxiliary space 212 therein, a second neck 220 coupled to an upper end of the second body 210, and a second head 230 coupled to an upper ends of the second neck 220. The second ring 211 is arranged inside the auxiliary space 212, and is coupled to the inner surface of the second body 210.

The control apparatus for vehicle 10 for a vehicle according to an embodiment of the disclosure further includes a mounting bracket 12 formed outside the housing 11, and an auxiliary fastening hole 14 formed on at least a portion of one surface of the mounting bracket 12. When the mounting bracket 12 is to be fastened to the outside of the housing 11, it may be fastened using a bolt 20. The process of fastening the housing 11 and the mounting bracket 12 is as follows.

The mounting bracket 12 is arranged on the outside the housing 11 so that the fastening hole 13 and the auxiliary fastening hole 14 overlap with each other. The bolt 20 is coupled to pass through the fastening hole 13 and the auxiliary fastening hole 14. An end of the bolt 20 is exposed towards the inside of the housing. The second protector 200 fit with the fastening hole 13 to surround the end portion of the bolt 20.

According to an embodiment of the disclosure, the second protector 200 is interference-fitted with the fastening hole 13 to close the housing 11. When the second protector 200 is fitted to the fastening hole 13, the second body 210 is positioned inside the housing 11. The second head 230 is positioned outside the housing 11, and the second neck 220 is positioned inside the fastening hole 13.

At least a portion of the second head 230 is in contact with the outer surface of the housing 11, and at least a portion of a second body 210 is in contact with an inner surface of the housing 11. When the second head 230 and the outer surface of the housing 11 come into contact with each other, a frictional force is generated, allowing the second head 230 to be fixed.

The second head 230 is formed to have an annular shape and is formed to surround the bolt 20. The outer diameter of the second head 230 is formed to be greater than the diameter of the fastening hole 13. When the second protector 200 is fitted to the fastening hole 13, at least a portion of the second head 230 is exposed toward the outside of the housing 11.

When the housing 11 and the mounting bracket 12 are to be fastened according to an embodiment of the disclosure, a gap may be formed between the housing 11 and the mounting bracket 12. The second head 230 is positioned in the gap formed between the housing 11 and the mounting bracket 12, and the second head 230 is in close contact with the housing 11 and the mounting bracket 12.

The second head 230 may secure the second protector 200. When a force directed toward the inside of the control apparatus for vehicle 10 is applied to the second protector 200, the second protector 220 does not detach from the fastening hole 13.

According to an embodiment of the disclosure, the second body 210 may include a second receiving space (not shown) therein. When the second protector is fitted to the fastening hole 13 to which the bolt 20 is fastened, the bolt 20 is positioned inside the second receiving space.

The second body 210 is formed to have a diameter greater than the diameter of the fastening hole 13. When the second protector 200 is fitted to the fastening hole 13, the second body 210 is positioned toward the inside of the housing 11, and at least a portion of the second body 210 comes into contact with the inner surface of the housing 11. A frictional force is generated between the second body 210 and the inner surface of the housing 11, allowing the second body 210 to be fixed. When a force directed toward the outside of the control apparatus for vehicle 10 is applied to the second protector 200, the second protector 220 does not detach from the fastening hole 13.

The second body 210 may further include an auxiliary space 212 therein. When the second protector 200 is fitted to the fastening hole 13, the auxiliary space 212 is formed to surround at least a portion of the bolt 20. When performing a process of fastening the bolt 20, the thread of the bolt 20 may wear out, generating powder. When continuous vibration is applied to the control apparatus for vehicle 10, the housing 11 or the bolts 20 may wear due to friction, generating powder. The powder generated from the outside of the housing 11 or from the thread of the bolt 20 falls through the fastening hole 13. The fallen powder does not scatter toward the inside of the housing 11 and is received in the auxiliary space 212.

The second ring 211 may be positioned inside the second receiving space. The second ring 211 contacts an inner surface of the second receiving space while being formed to be movable. The outer diameter of the second ring 211 is formed to be greater than the diameter of the fastening hole 13 so that the second ring 211 does not detach toward the outside of the second receiving space. When the second protector 200 is fitted to the fastening hole 13, the thread of the bolt 20 is in close contact with the inner surface of the second ring 211.

When the bolt 20 is fastened to the fastening hole 13, a gap may be formed in the threads of the bolt 20. The second ring 211 is fitted between the threads of the bolt 20. When the bolt 20 is rotated using a driver, the second ring 211 moves simultaneously with the threads. When the bolt 20 performs rotational motion, the second ring 211 may be deformed so as to fill the gap between the threads. The second ring 211 may be used to attach the bolt 20 to the housing 11 without applying the screw locking paint. When continuous vibration is applied toward the bolt 20, the second ring 211 may absorb the vibration.

The second neck 220 couples the second body 210 and the second head 230. The second neck 220 is formed to have an annular shape, so that the second receiving space of the second body 210 is exposed. The second neck 220 is formed such that the second body 210 and the second head 230 are spaced apart from each other by a predetermined distance, where the predetermined distance is formed to be equal to or less than a thickness of the housing 11. When the second protector 200 is fitted to the fastening hole 13, the second neck 220 is in close contact with the fastening hole 13.

According to an embodiment of the disclosure, the protectors 100, 200 may be formed using an ABS (acrylonitrile-butadiene-styrene) material which is a polymer plastic. ABS is formed by polymerizing acrylonitrile, butadiene, and styrene components. ABS is a material having excellent mechanical strength and impact resistance. ABS has excellent chemical resistance, and thus is not easily deformed even when in contact with acidic substances or organic solvents. ABS may have the properties of acrylonitrile, butadiene and styrene all together.

Acrylonitrile is a molecule in which one hydrogen atom of ethylene is substituted with a cyano group. Since acrylonitrile has electrical polarity, ABS has excellent chemical resistance including acrylonitrile.

Butadiene is a hydrocarbon including four carbon atoms and six hydrogen atoms. Butadiene is a diene having two double bonds, and when a polymer is polymerized using butadiene, a material having excellent elasticity may be formed. Butadiene is a main component of rubber. Since the ABS material has an elasticity, it may absorb impact energy without breaking even when subjected to impact.

Styrene is a molecule in which one hydrogen atom in an ethylene molecule is substituted with a benzene ring. When the protector 100, 200 is formed using styrene, the durability and strength of the protector may be increased.

The ABS material may be synthesized using an emulsion polymerization or bulk polymerization method. The emulsion polymerization method is a method in which water is used as a dispersion medium (solvent), monomers are dispersed together with a surfactant, and then a polymerization reaction is carried out. When performing the emulsion polymerization method, small polymer particles (latex) are formed in water. The emulsion polymerization method has an advantage in that it may uniformly obtain polymer materials.

The emulsion polymerization method includes a process of dispersing monomers in water together with a surfactant, a process of adding an initiator to induce a radical reaction, a process in which the polymer particles grow as the radical reaction proceeds, a process of injecting a coagulant to terminate the polymerization, and a drying process.

The bulk polymerization method is a method of directly polymerizing using only monomers and an initiator without a solvent. When using the bulk polymerization method, it is possible to produce a transparent and pure polymer with almost no impurities. The bulk polymerization method does not use a solvent and therefore does not require a solvent removal process. Although the bulk polymerization method allows for designing an efficient process, it has a disadvantage in that it is difficult to control the temperature due to a large amount of heat generation.

According to an embodiment of the disclosure, the monomers may be acrylonitrile, styrene and butadiene. The ABS material may adjust the ratio of acrylonitrile, butadiene, and styrene to change durability and elasticity. By adjusting the ratio of the monomers, the protector 100, 200 having durability or elasticity above a certain standard may be manufactured.

According to an embodiment of the disclosure, the protector 100, 200 may be manufactured using an insert injection process. The inserting process is a process of molding a molded product by inserting a material to be molded and a component configured using a material different from that to be molded.

When molding the protector 100, 200 using the insert process, a metal component or other plastic material may be inserted into the plastic material to increase the hardness. Furthermore, the hardness of the protectors 100, 200 may be adjusted by adjusting the insertion ratio of metal component or other materials.

The injection process is a process in which the material to be molded is inserted into a mold for molding. When the protector 100, 200 is manufactured using the insert injection process, it is possible to manufacture the protector 100, 200 by preparing a mold to be molded according to the diameter of the fastening hole 13, and the diameters of the head 130, 230, neck 120, 220, and body 110, 210,

The above description is merely illustrative of the technical spirit of the embodiment, and various modifications and variations will be possible to by those of ordinary skill in the art to which the embodiment pertains, without departing from the essential characteristics of the embodiment. Therefore, the embodiments are not intended to limit but to explain the technical spirit of the embodiment, and the scope of the technical spirit of the embodiment is not limited by these embodiments. The scope of protection of the embodiment should be interpreted by the following claims, and all technical spirit within the equivalent scope thereof should be interpreted as being included in the scope of rights of the embodiment.

### DESCRIPTION OF SIGNS

10: Control apparatus for vehicle
11: Housing
12: Mounting bracket
13: Fastening hole
14: Auxiliary fastening hole
15: PCB
20: Bolt
100: First protector
110: First body
111: First ring
112: First receiving space
120: First neck
130: First head
200: Second protector
210: Second body
211: Second ring
212: Auxiliary space
220: Second neck
230: Second head
A: Powder
B: Foreign material

1. A protector configured to fit with a housing, the protector comprising:
a first body comprising a first receiving space in the first body;
a first neck coupled to an upper end of the first body;
a first head coupled to an upper end of the first neck; and
a first ring disposed in the first receiving space and in contact with an inner surface of the first body,
wherein the housing comprises a fastening hole disposed on at least a portion of one surface of the housing.

2. The protector of claim 1, wherein the first body fits with the fastening hole, the first head is disposed outside the housing, and the first neck is disposed inside the fastening hole.

3. The protector of claim 1, wherein the first head is formed to have an annular shape, and has an outer diameter greater than a diameter of the fastening hole.

4. The protector of claim 1, wherein the first body has a diameter greater than a diameter of the fastening hole.

5. The protector of claim 1, wherein the first neck is formed to have an annular shape, and is disposed so that the first head and the first body are spaced apart from each other by a predetermined distance, and
wherein the predetermined distance is equal to or less than a thickness of the housing.

6. A protector configured to fit with a housing, the protector comprising:
a second body comprising a second receiving space in the second body;
a second neck coupled to an upper end of the second body;
a second head coupled to an upper end of the second neck; and
a second ring disposed in the second receiving space and in contact with an inner surface of the second body,
wherein the housing comprises a fastening hole disposed on at least a portion of one surface of the housing,
wherein a mounting bracket is disposed outside the housing, and
wherein the mounting bracket comprises an auxiliary fastening hole disposed on at least a portion of one surface of the mounting bracket.

7. The protector of claim 6, wherein the fastening hole and the auxiliary fastening hole are screw-coupled using a bolt, the second receiving space is disposed so that the bolt is positioned therein, and

8. The protector of claim 7, wherein the second body fits with the fastening hole, the second head is disposed outside the housing, and the second neck is disposed inside the fastening hole.

9. The protector of claim 7, wherein the second body further comprises an auxiliary space in the second body, and the auxiliary space is disposed to surround at least a portion of the bolt.

10. The protector of claim 6, wherein the second body fits with the fastening hole, the second body is positioned inside the housing, and the second ring is disposed to be attached to threads of the bolt.

11. The protector of claim 10, wherein the second head is formed to have an annular shape, and has an outer diameter greater than a diameter of the fastening hole.

12. The protector of claim 10, wherein the second body has a diameter greater than a diameter of the fastening hole.

13. The protector of claim 10, wherein the second neck is formed to have an annular shape, and is disposed so that the second head and the second body are spaced apart from each other by a predetermined distance, and wherein the predetermined distance is equal to or less than a thickness of the housing.

14. A vehicle comprising:
a control apparatus comprising:
a housing including a fastening hole disposed on at least a portion of one surface of the housing; and
a protector coupled to the housing;
wherein the protector comprising:
a body including a receiving space in the body;
a neck coupled to an upper end of the body;
a head coupled to an upper end of the neck; and
a ring disposed in the receiving space and in contact with an inner surface of the body,
wherein the protector is coupled to the fastening hole of the housing.

15. The vehicle of claim 14, wherein the body fits with the fastening hole, the head is disposed outside the housing, and the neck is disposed inside the fastening hole.

16. The vehicle of claim 14, wherein the control apparatus further comprises:
a mounting bracket disposed outside the housing and including an auxiliary fastening hole disposed on at least a portion of one surface of the mounting bracket.

17. The vehicle of claim 16, wherein the control apparatus further comprises a bolt, the fastening hole and the auxiliary fastening hole are screw-coupled using the bolt, and the receiving space is disposed so that the bolt is positioned therein, and

18. The vehicle of claim 17, wherein the body further comprises an auxiliary space in the body, and the auxiliary space is disposed to surround at least a portion of the bolt.

19. The protector of claim 18, wherein the body fits with the fastening hole, the body is positioned inside the housing, and the ring is disposed to be attached to threads of the bolt.
